(19) United States
(12) Patent Application Publication
(10) Pub. No.: US 2026/0088735 A1
(43) Pub. Date: Mar. 26, 2026

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP); Shunya MIYAZAKI, Fukuoka (JP)

(73) Assignee: TOTO LTD., Fukuoka (JP)

(21) Appl. No.: 19/285,311

(22) Filed: Jul. 30, 2025

(30) Foreign Application Priority Data
Sep. 24, 2024 (JP) 2024-165032

(51) Int. Cl. H02N 13/00; H01L 21/683

(52) U.S. Cl. CPC H02N 13/00; H10P 72/722

(57) ABSTRACT

To provide an electrostatic chuck which has a configuration in which a conductive member is arranged between a dielectric substrate and a base plate, and can be easily manufactured.

An electrostatic chuck 10 includes a dielectric substrate 100, an RF electrode 140 provided inside the dielectric substrate 100, a base plate 200 made of metal and joined to the dielectric substrate 100, and a conductive member 400 configured to electrically connect the RF electrode 140 and the base plate 200 to each other. A recessed section 270 which accommodates a part of the conductive member 400 is formed in a surface 210 on the dielectric substrate 100 side of the base plate 200. In this electrostatic chuck 10, a length (L2) of a part of the conductive member 400 accommodated in the recessed section 270 is ½ or more of the entire length (L1) of the conductive member 400.

### CROSS-REFERENCE TO RELATED APPLICATION

This application is based upon and claims the benefit of priority from Japanese Patent Application No. 2024-165032 filed on Sep. 24, 2024, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to adsorb and hold a wafer such as a silicon wafer to be processed. The electrostatic chuck includes a dielectric substrate to which an adsorption electrode is provided and a base plate which supports the dielectric substrate, and has a configuration in which these are joined to each other. When a voltage is applied to the adsorption electrode, an electrostatic force is generated, and the wafer placed on the dielectric substrate is adsorbed and held.

As described in International Publication No. WO 2022/255118, an RF electrode serving as one of a pair of counter electrodes configured to generate plasma in a semiconductor manufacturing apparatus may be built in the dielectric substrate. In this case, the RF electrode and the base plate are electrically connected to each other via a conductive member. According to this, a potential of the RF electrode during a process of the wafer is kept at a potential of the base plate.

### SUMMARY

To electrically connect the conductive member and the RF electrode to each other, for example, a recessed section may be formed in a surface on the base plate side in the dielectric substrate, and while the RF electrode is exposed in a bottom of the recessed section, the conductive member may be accommodated in an inner side of the recessed section. Similarly, to electrically connect the base plate and the RF electrode to each other, for example, a recessed section may be formed in a surface on the dielectric substrate side in the base plate, and the conductive member may be accommodated in the inner side of the recessed section. In this case, a part of the conductive member is accommodated in the recessed section of the dielectric substrate, and another part is accommodated in the recessed section of the base plate.

In manufacturing the electrostatic chuck having the above-described configuration, after a part of the conductive member is inserted into a recessed section provided on an upper surface of the base plate, and the conductive member is projected from the upper surface of the base plate, the base plate and the dielectric substrate may be joined to each other with a silicone adhesive and the like. At this point, if the recessed section formed on the upper surface of the base plate is too shallow, the conductive member tends to easily fall down at the time of joining and the like, so that workability is significantly lowered.

The present invention has been made in view of the above-mentioned issue and is aimed to provide an electrostatic chuck which has a configuration in which a conductive member is arranged between a dielectric substrate and a base plate, and can be easily manufactured.

To address the above-mentioned issue, an electrostatic chuck according to an aspect of the present invention includes a dielectric substrate including a placement surface on which an object to be adsorbed is placed, an internal electrode provided inside the dielectric substrate, a base plate made of a metal and joined to the dielectric substrate, and a conductive member configured to electrically connect the internal electrode and the base plate to each other. A recessed section which accommodates a part of the conductive member is formed in a surface on the dielectric substrate side of the base plate. In this electrostatic chuck, a length of a part of the conductive member accommodated in the recessed section along a direction perpendicular to the placement surface is ½ or more of the entire length of the conductive member along the same direction.

In the electrostatic chuck having such a configuration, the recessed section formed in the base plate is sufficiently deep, and the depth thereof is ½ or more of the entire length of the conductive member. The conductive member inserted into the recessed section before joining is prevented from falling down thereafter, so that work of joining the dielectric substrate to the base plate and the like can be easily performed.

According to the present invention, it is possible to provide an electrostatic chuck which has a configuration in which a conductive member is arranged between a dielectric substrate and a base plate, and can be easily manufactured.

### BRIEF DESCRIPTION OF THE DRAWINGS

FIG. 1 is a cross sectional view schematically illustrating a configuration of an electrostatic chuck according to the present embodiment;

FIG. 2 is an enlarged view of a configuration of a conductive member and its neighboring part in the electrostatic chuck in FIG. 1; and

FIG. 3 is a perspective view illustrating the configuration of the conductive member.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W that is an object to be adsorbed is, for example, a silicon wafer. The electrostatic chuck 10 may be used in an apparatus other than the semiconductor manufacturing apparatus.

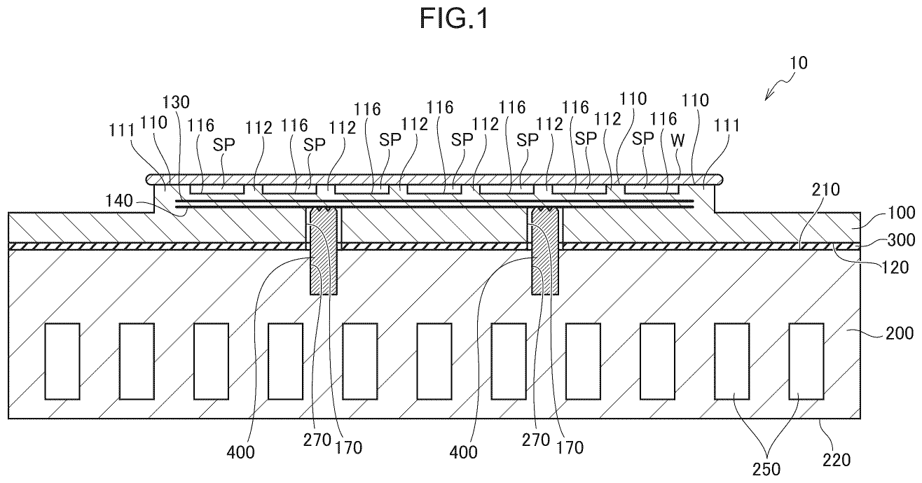

FIG. 1 is a cross sectional view schematically illustrating a configuration of the electrostatic chuck 10 in a state in which the wafer W is adsorbed and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An adsorption electrode 130 is embedded inside the dielectric substrate 100. The adsorption electrode 130 is a thin planar layer made of a metallic material such as, for example, tungsten, and is arranged so as to be parallel to the surface 110. As a material of the adsorption electrode 130, molybdenum, platinum, palladium, and the like may be used in addition to tungsten. When a voltage is applied to the adsorption electrode 130 from an outside via a feed line which is not illustrated in the drawing, an electrostatic force is generated between the surface 110 and the wafer W, and according to this, the wafer W is adsorbed and held. As a configuration of the above-described feed line, various configurations in related art can be adopted. The single adsorption electrode 130 may be provided as so-called a “monopolar” electrode as in the present embodiment, but may also include two adsorption electrodes as so-called “bipolar” electrodes.

In addition to the above-described adsorption electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side of the electrostatic chuck 10 in the semiconductor manufacturing apparatus. When a high-frequency alternating-current voltage is applied between the counter electrodes, plasma is generated on the upper side of the wafer W and used for processing such as film deposition and etching on the wafer W. The RF electrode 140 corresponds to an “internal electrode” according to the present embodiment.

Similarly, as in the adsorption electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded at a position on the surface 120 side than the adsorption electrode 130. Similarly to the adsorption electrode 130, the RF electrode 140 is disposed in parallel to the surface 110. The RF electrode 140 is a single electrode which is substantially circular in top view. In top view, a center of the RF electrode 140 matches a center of the dielectric substrate 100.

A conductive member 400 is provided in the electrostatic chuck 10. The conductive member 400 is a member configured to electrically connect the RF electrode 140 and the base plate 200 which will be described below to each other. By the conductive member 400, a potential of the RF electrode 140 during the process on the wafer W becomes the same as a potential of the base plate 200. The conductive member 400 includes a plurality of conductive members 400 which are provided in the electrostatic chuck 10, but FIG. 1 illustrates only two of the conductive members 400. The number of the conductive members 400 provided in the electrostatic chuck 10 may be only one. A specific shape and the like of the conductive member 400 will be described later.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100.

The joining layer 300 is a layer provided between the dielectric substrate 100 and the base plate 200 to join those components. The joining layer 300 is provided by causing an adhesive made of an insulating material to be cured. According to the present embodiment, a silicone adhesive is used as the above-described adhesive. It is noted however that the joining layer 300 may be provided by causing an adhesive of other types to be cured. In any case, in order that a thermal resistance between the dielectric substrate 100 and the base plate 200 is reduced, a material with a highest possible thermal conductivity may be used as the material of the joining layer 300.

An insulating film may be formed on a surface of the base plate 200. As the insulating film, for example, an alumina film formed by thermal splaying can be used. When the surface of the base plate 200 is covered by the insulating film, a withstand voltage of the base plate 200 may be increased.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

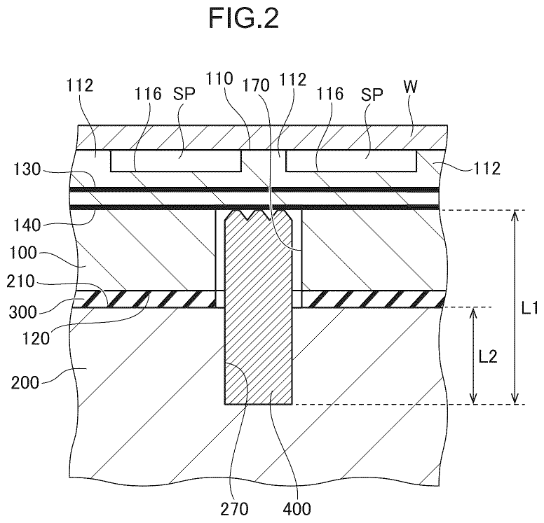

A specific configuration of the conductive member 400 and its neighboring part will be described. FIG. 2 is an enlarged view of the configuration of the conductive member 400 and its neighboring part in the electrostatic chuck 10 in FIG. 1. As illustrated in FIG. 2, a recessed section 170 is formed in the surface 120 on the base plate 200 side of the dielectric substrate 100. The recessed section 170 is a part obtained by causing a part of the surface 120 to retreat towards the surface 110 in a recessed shape to enable the conductive member 400 to be arranged. The recessed section 170 of the present embodiment is formed up to a depth position in which the RF electrode 140 is to be exposed. For this reason, the RF electrode 140 serving as the internal electrode is exposed in a bottom (which can be also referred to as an upper end surface) of the recessed section 170. A shape of the recessed section 170 in top view is circular, and a space of a substantially cylindrical shape is formed on an inner side of the recessed section 170.

A recessed section 270 is formed in the surface 210 on the dielectric substrate 100 side of the base plate 200. The recessed section 270 is formed in a portion that overlaps with the recessed section 170 in the surface 210 in top view. The recessed section 270 is a part obtained by causing a part of the surface 210 to retreat towards the surface 220 in a recessed shape to enable the conductive member 400 to be arranged. A metallic part of the base plate 200 is exposed on an inner side of the recessed section 270 throughout the entirety. A shape of the recessed section 270 in top view is circular, and a space of a substantially cylindrical shape is formed on an inner side of the recessed section 270. A central axis of the recessed section 270 matches a central axis of the recessed section 170. An inner diameter of the recessed section 270 is smaller than an inner diameter of the recessed section 170.

A circular opening is formed in a part between the recessed section 170 and the recessed section 270 in the joining layer 300. The recessed section 170 and the recessed section 270 are connected to each other via the opening, and a whole of these becomes one space.

The conductive member 400 is a member of a substantially cylindrical shape which is formed of a fibrous metal member, and is accommodated in the inner sides of the recessed section 170 and the recessed section 270. That is, a part of the conductive member 400 is accommodated in the recessed section 170, and another part of the conductive member 400 is accommodated in the recessed section 270. In top view, a diameter of a part of the conductive member 400 accommodated in the recessed section 270 is substantially equal to the inner diameter of the recessed section 270.

The conductive member 400 abuts against the RF electrode 140 exposed in the bottom of the recessed section 170. The conductive member 400 also abuts against the metallic part of the base plate 200 which is exposed in a bottom of the recessed section 270. The RF electrode 140 and the metallic part of the base plate 200 are electrically connected to each other by the thus arranged conductive member 400.

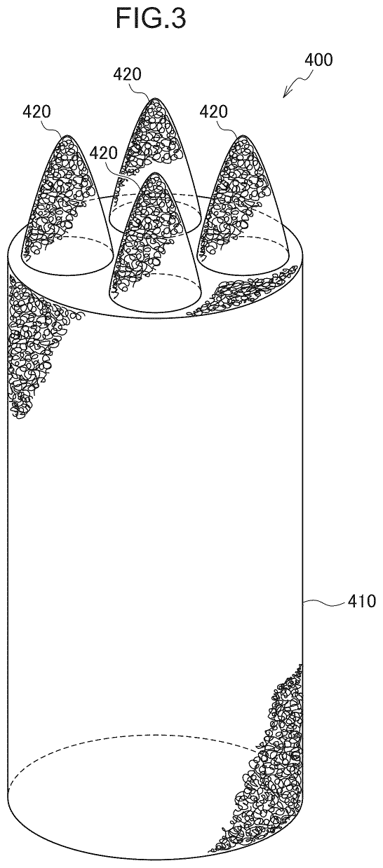

As illustrated in FIG. 3, the conductive member 400 includes a main body section 410 of a substantially cylindrical shape and a plurality of protrusion sections 420, and an entirety thereof is integrally formed of the fibrous metal member. The protrusion section 420 is a protrusion of a substantially cylindrical shape which is formed so as to extend from the surface on the dielectric substrate 100 side in the main body section 410 further towards the dielectric substrate 100. According to the present embodiment, four in total of the protrusion sections 420 are formed, but the number of the protrusion sections 420 may be different from four.

The conductive member 400 formed of the fibrous metal member has a breathability to such an extent that allows a fluid such as air to intrude into the inside of the conductive member 400. That is, the fibrous metal member is not sufficiently dense, and there is a gap between mutual fibers. When such a configuration is adopted, the conductive member 400 serves as an elastic body in which each section including the protrusion section 420 may be easily deformed by an external force.

A dimension in an up and down direction (direction in which the protrusion section 420 extends) of the conductive member 400 when the external force is not received is larger than a dimension in the same direction (L1 in FIG. 2) in the state of FIG. 2. That is, in a state in which the conductive member 400 is compressed along the direction from the dielectric substrate 100 towards the base plate 200, the conductive member 400 is accommodated in the inner sides of the recessed section 170 and the recessed section 270 and sandwiched between the RF electrode 140 and the base plate 200. A distal end of each of the protrusion sections 420 is elastically deformed so as to collapse by being pressed against the bottom of the recessed section 170 (that is, the RF electrode 140).

The conductive member 400 is in a state of being pressed against each of the RF electrode 140 and the base plate 200 by its own restoring force. For this reason, during the process on the wafer W or the like, even when a thermal expansion or contraction occurs in each section of the electrostatic chuck 10, the electrical connection between the RF electrode 140 and the base plate 200 is regularly maintained.

A shape different from that of the present embodiment may be adopted as the shape of the conductive member 400. For example, the entirety of the conductive member 400 may have a substantially cylindrical shape and a shape without including the protrusion section 420.

Returning to FIG. 2, the description will be continued. In FIG. 2, “L1” is a length of the entire conductive member 400 along a direction perpendicular to the placement surface. Specifically, it is the entire length of the conductive member 400 when the conductive member 400 is accommodated and compressed inside the recessed section 170 and the recessed section 270. L1 is equal to a distance from the bottom of the recessed section 170 to the bottom of the recessed section 270.

In FIG. 2, “L2” is a length of a part of the conductive member 400 accommodated in the recessed section 270 along the direction perpendicular to the placement surface. L2 is equal to a distance from the surface 210 to the bottom of the recessed section 270, that is, a depth of the recessed section 270.

In the present embodiment, respective shapes of the conductive member 400, the recessed section 170, and the recessed section 270 are adjusted so that L2 becomes a length of ½ or more of L1. The reason for this configuration will be described below.

In manufacturing the electrostatic chuck 10, after a part of the conductive member 400 is inserted into the recessed section 270 provided in the surface 210 of the base plate 200, and the conductive member 400 is projected from the surface 210, the base plate 200 and the dielectric substrate 100 may be joined to each other with a silicone adhesive and the like. At this point, if the recessed section 270 formed in the surface 210 is too shallow, the conductive member 400 tends to easily fall down at the time of joining and the like, so that workability is significantly lowered.

Thus, in the present embodiment, the depth (L2) of the recessed section 270 formed in the surface 210 is sufficiently deep as described above, which is a depth of ½ or more of the entire length (L1) of the conductive member 400. With such a configuration, the conductive member 400 inserted into the recessed section 270 before joining is prevented from falling down thereafter, so that work of joining the dielectric substrate 100 to the base plate 200 and the like can be easily performed.

The depth of the recessed section 270 may be adjusted so that L2≥L1 is satisfied even in a case where a length before the conductive member 400 is compressed is assumed to be L1.

In the present embodiment, after the RF electrode 140 is exposed at the bottom of the recessed section 170, an upper end of the conductive member 400 is caused to directly abut against the RF electrode 140. Instead of such an aspect, the recessed section 170 may be formed to be shallower than the present embodiment, and the RF electrode 140 may be prevented from being exposed at the bottom thereof. In this case, for example, a via (hole filled with a conductor) extending from the bottom of the recessed section 170 to the RF electrode 140 may be formed, and the upper end of the conductive member 400 may be electrically connected with the RF electrode 140 through the via.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be adsorbed is placed;
an internal electrode provided inside the dielectric substrate;
a base plate made of metal and joined to the dielectric substrate; and
a conductive member configured to electrically connect the internal electrode and the base plate to each other, wherein
a recessed section configured to accommodate a part of the conductive member is formed on a surface on the dielectric substrate side of the base plate, and
a length of a part of the conductive member accommodated in the recessed section along a direction perpendicular to the placement surface is ½ or more of the entire length of the conductive member along the same direction.
